(19) United States
(12) Patent Application Publication
(10) Pub. No.: US 2026/0031155 A1
(43) Pub. Date: Jan. 29, 2026

(54) CAPACITOR STRUCTURE USING SURFACES OF THREE DIMENSIONAL STRUCTURES FORMED ACROSS MULTIPLE METALLIZATION LAYERS

(71) Applicant: Micron Technology, Inc., Boise, ID (US)

(72) Inventors: Martin Walter POPP, Meridian, ID (US); Pratap MURALI, Meridian, ID (US)

(21) Appl. No.: 19/226,255

(22) Filed: Jun. 3, 2025

Related U.S. Application Data
(60) Provisional application No. 63/674,636, filed on Jul. 23, 2024.

(51) Int. Cl. G11C 16/30; G11C 16/04; H10D 1/00; H10D 1/68

(52) U.S. Cl. CPC G11C 16/30; G11C 16/0483; H10D 1/043; H10D 1/714; H10D 1/716

(57) ABSTRACT

Implementations described herein relate to various structures, integrated assemblies, and memory devices. In some implementations, an integrated assembly includes a layered structure. The layered structure includes a first set of conductive structures that are horizontally formed in a first metallization layer, a second set of conductive structures that are horizontally formed in a second metallization layer, and a set of interconnect structures that is vertically formed and electrically couples the first set of conductive structures and the second set of conductive structures. The layered structure further includes conformal dielectric layer over surfaces of the first set of conductive structures, surfaces of the second set of conductive structures, and surfaces the set of interconnect structures. The layered structure further includes a conductive fill structure that surrounds the conformal dielectric layer.

### CROSS-REFERENCE TO RELATED APPLICATION

This Patent application claims priority to U.S. Provisional Patent Application No. 63/674,636, filed on Jul. 23, 2024, entitled “CAPACITOR STRUCTURE USING SURFACES OF THREE DIMENSIONAL STRUCTURES FORMEDACROSS MULTIPLE METALLIZATION LAYERS,” and assigned to the assignee hereof. The disclosure of the prior Application is considered part of and is incorporated by reference into this Patent Application.

### TECHNICAL FIELD

The field of semiconductor device fabrication encompasses the creation and refinement of various components for electronic circuits. This domain includes the development of capacitor structures to meet the requirements of integrated circuit functionality.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell described herein.

FIG. 2 is an example diagrammatic view of an example charge pump circuit described herein.

FIG. 3 shows a diagrammatic side view of a semiconductor device described herein.

FIG. 4 is a diagrammatic view of an example implementation of a set of conductive structures described herein.

FIG. 5 is a flowchart of an example method of forming an integrated assembly or memory device having a stack of metallization layers described herein.

FIG. 6 is a flowchart of an example method of forming an integrated assembly or memory device having a capacitor structure described herein.

FIG. 7A through FIG. 7H are diagrammatic views showing formation of a capacitor structure at example process stages of an example process of forming the capacitor structure.

FIG. 8 is a diagram of an example implementation of a memory array described herein.

### DETAILED DESCRIPTION

In the field of semiconductor memory devices, such as NAND flash memory, there is an ongoing challenge to increase storage density while maintaining or improving device efficiency and performance. One critical component in NAND memory devices is the charge pump, which is necessary for providing the high voltages required for NAND operation. As NAND technology advances and three dimensional storage density increases, the need for more efficient charge pumps becomes apparent. These charge pumps traditionally rely on metal-insulator-metal (MIM) capacitors to generate the necessary high voltages, often exceeding 30V.

In some cases, a construction of a MIM capacitor using standard metal layers presents several limitations. For example, a charge capacity of the MIM capacitor may be constrained by lithographic critical dimensions (CD), such as metal space and line width. Additionally, or alternatively, a dielectric material used is often an interlayer dielectric (ILD) material, which is not ideal for MIM capacitor applications. Additionally, or alternatively, a capacitor layout (e.g., a layout including comb-like conductive structures used to form cell plates or electrodes) can extend over multiple metallization layers, but fail to efficiently utilize available space for capacitive structures. As a result, there are technical challenges in effectively increasing the capacitance per area without compromising the performance and scalability of the device.

Furthermore, the process of constructing such a layout may pose additional challenges. For example, the layout may be limited by photolithographic resolution, and thicknesses of dielectric materials may scale with voltage break down thresholds. These factors, combined with the constraints of existing manufacturing processes, create complexities that may inhibit increasing capacitance densities of capacitors in semiconductor devices. Addressing these technical problems requires an approach that allows for increased capacitance per area while being compatible with current manufacturing techniques and accommodating the demands of higher voltage operations.

Some implementations described herein provide an integrated assembly that significantly increases the capacitance per area for a capacitor in a semiconductor device. For example, the integrated assembly comprises a layered structure with two or more sets of conductive structures in separate metallization layers, electrically connected by interconnect structures. A conformal dielectric layer is applied to the surfaces of these conductive structures and interconnects, and then a conductive fill structure surrounds the conformal dielectric layer.

In some aspects, the method includes receiving a layer stack with conductive structures across multiple metallization layers, forming a sacrificial layer and creating an opening that exposes the uppermost conductive structures. Portions of the dielectric layers are removed to expose all the conductive surfaces, upon which a conformal dielectric layer is formed, followed by the removal of the sacrificial layer. Another method involves removing portions of insulative layers to expose electrode structures and interconnects, forming a conformal dielectric layer on these surfaces, and then surrounding this structure with a three-dimensional electrode.

In this way, the implementations address the technical challenge of increasing memory storage density by using available three dimensional surface of one or several interconnect structures as a capacitor, thus significantly increasing capacitance per area (footprint). This implementations are scalable by adding more metallization layers and utilize a dedicated dielectric to optimize MIM capacitor characteristics, thereby overcoming the limitations of standard MIM capacitor configurations and traditional photolithographic processes.

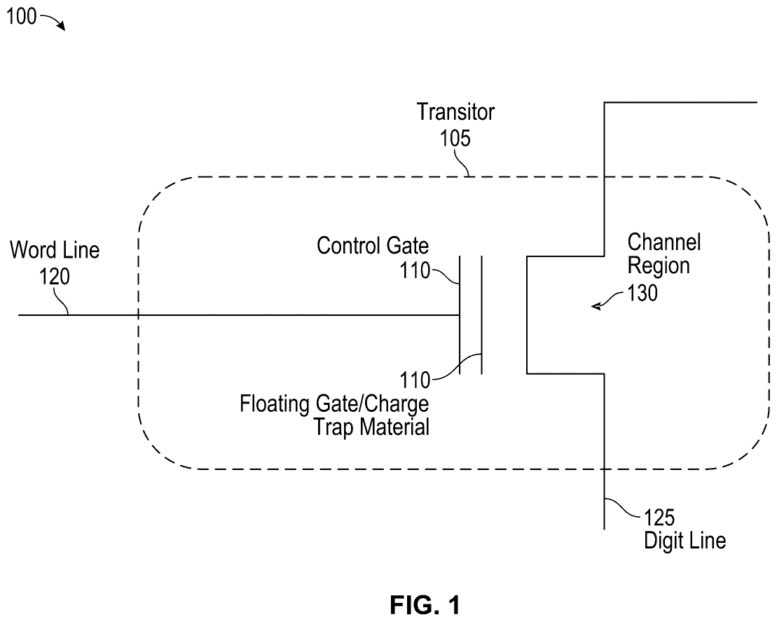

FIG. 1 is a circuit diagram of an example memory cell 100 described herein. In some implementations, the memory cell 100 is a NAND memory cell. As shown in FIG. 1, the memory cell 100 may include a transistor 105 that includes a control gate 110, a floating gate/charge trap material 115, and a channel region 130.

The transistor 105 may store bits of data by trapping electrons on the floating gate/charge trap material 115. For example, a presence of electrons (e.g., trapped electrons) on the floating gate/charge trap material 115 may correspond to a logic state “0,” while an absence of electrons from the floating gate/charge trap material 115 may correspond to a logic state “1.” In some implementations, the floating gate/charge trap material 115 may be a floating gate. In some implementations, the floating gate/charge trap material may be a charge trap material. Use of the transistor 105 allows for non-volatile data storage, meaning that the data persists even if power is removed from the memory cell 100. As such, a capacitor that may be used in other types of memory cells is not needed.

The transistor 105 (e.g., the memory cell 100) may be accessed (e.g., written to, read from, or erased) using signals on a combination of lines that are coupled to transistor 105, shown as a word line 120 (sometimes called an “access line”) that is connected to the control gate 110 and a digit line 125 (sometimes called a “bit line”) that is connected to a channel region 130.

Writing data to or reading data from the transistor 105 may involve applying different sets of voltages to the control gate 110 (via the word line 120) and the digit line 125. A first set of voltages may create a first electric field in the channel region 130 that facilitates movement and trapping of electrons onto the floating gate/charge trap material 115, establishing the logic state “0.” A second set of voltages may create a second electric field in the channel region 130 that facilitates movement and removal of electrons from the floating gate/charge trap material 115, establishing the logic state “1.” A third set of specific voltages may create a third electric field in the channel region 130 that facilitates a measurement of a threshold voltage of the transistor 105 that corresponds to a logic state.

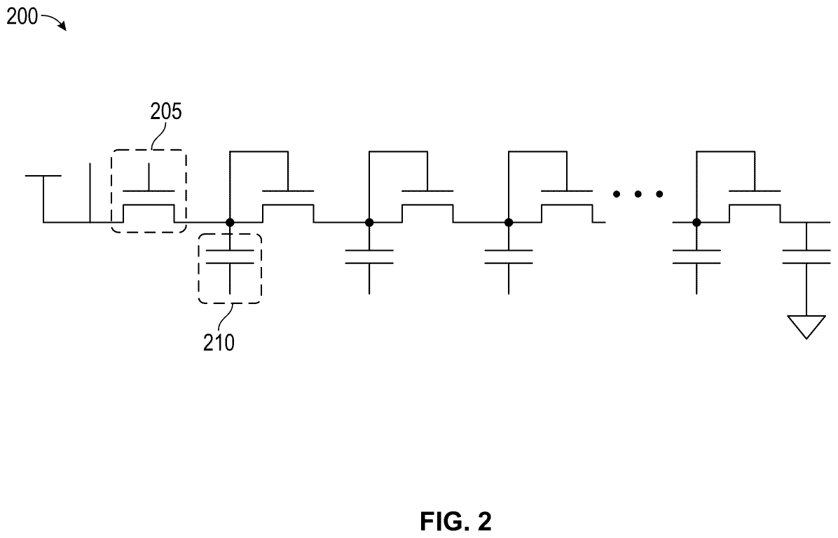

As described in greater detail in connection with FIGS. 2-8, and in some implementations, a charge pump circuit is used to generate a voltage level for various operations, including programming and erasing of the memory cell 100. The charge pump circuit may include a capacitor structure that uses surfaces of three dimensional structures formed across multiple metallization layers of a semiconductor device including the memory cell 100.

As indicated above, FIG. 1 is provided as an example. Other examples may differ from what is described with respect to FIG. 1.

FIG. 2 is an example diagrammatic view of an example charge pump 200 described herein. In some implementations, the charge pump 200 is electrically coupled with the memory cell 100 of FIG. 1.

The charge pump 200 (e.g., a voltage multiplier circuit), leverages a series of transistor structures 205 and capacitor structures 210 to amplify voltages. The charge pump 200 operates through a cyclical process of charging and discharging the capacitor structures 210, enabling the generation of an output voltage higher than the input.

During the charging phase, the transistor structure 205 connected to an input voltage source permits current flow, charging the capacitor structure 210 to the input voltage level. In the subsequent discharging phase, the capacitor structure 210 (e.g., a charged capacitor structure) is isolated from the input source as the transistor structure 205 switches off. Another transistor structure 205, linked to a higher voltage level, facilitates the discharge of the capacitor structure 210 into the next stage, effectively doubling the voltage across it.

The cycle repeats for each stage of transistor structures 205 and capacitor structures 210, with each stage multiplying the voltage from the preceding one. Through cascading multiple stages, the charge pump 200 achieves significantly elevated output voltages compared to the input. By orchestrating the timing and switching of the transistor structures 205, the charge pump 200 ensures efficient voltage multiplication, rendering it applicable across various scenarios requiring higher voltages with relatively lower inputs.

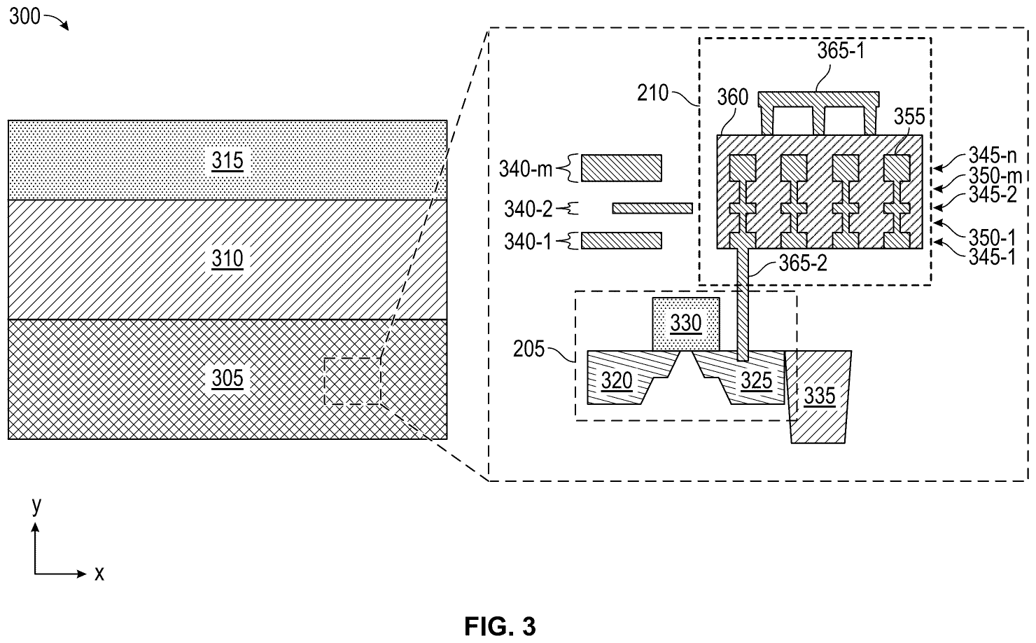

As described in greater detail in connection with FIG. 3 through FIG. 8, the capacitor structure 210 may include different configurations or features, such as sets of conductive structures that are joined by interconnect structures. In some implementations, a conformal dielectric layer may be over surfaces of the sets of conductive structures and a conductive fill structure may surround the conformal dielectric layer to form the capacitor structure 210.

Additionally, or alternatively and in implementations, the charge pump 200 is part of an integrated circuit that is a NAND memory circuit. In such implementations, the charge pump 200 may be configured to generate a voltage that is greater than or equal to a threshold voltage (e.g., approximately 30 volts). If the voltage is less than approximately 30 volts, a programming error (e.g., a read/write error to a memory cell of the NAND memory circuit) may occur. However, other values or ranges for the voltage generated by the charge pump 200 are within the scope of the present disclosure.

As indicated above, FIG. 2 is provided as an example. Other examples may differ from what is described with regard to FIG. 2.

FIG. 3 shows a diagrammatic side view of a semiconductor device 300 described herein. As shown in FIG. 3, the semiconductor device 300, which may be a NAND semiconductor device, may include a device region 305, a cell stack region 310, and an interconnect region 315. The device region 305 may include integrated circuitry including one or more portions of the charge pump 200 of FIG. 2. The cell stack region 310 may include integrated circuitry including one or more portions of the memory cell 100 of FIG. 1. The interconnect region 315 (sometimes referred to as a backend of line (BEOL) region) may include traces or interconnects for electrically coupling integrated circuitry of the device region 305 or the cell stack region 310 with another device external to the semiconductor device 300.

As shown in the detailed view of FIG. 3, the device region 305 includes the transistor structure 205, which includes a source region 320, a drain region 325, and gate structure 330. The source region 320 or the drain region 325 may be a semiconductor and may comprise, consist of, or consist essentially of semiconductive material. The semiconductive material may comprise, consist of, or consist essentially of silicon (e.g., polycrystalline silicon), among other examples. In some implementations, the source region 320 may be a same material as or a different material than the drain region 325. In some implementations, the source region 320 or the drain region 325 include a dopant that changes electrical conductivity properties of the source region 320 or the drain region 325.

The gate structure 330 may be an electrical conductor and may comprise, consist of, or consist essentially of conductive material. The conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide), among other examples.

In some implementations, a shallow trench isolation (STI) region 335 is proximate to the transistor structure 205. The STI region 335, which may electrically isolate the transistor structure 205 from other structures or integrated circuitry within the device region 305, may be an electrical insulator and may comprise, consist of, or consist essentially of insulative material. The insulative material may comprise, consist of, or consist essentially of silicon dioxide or silicon nitride, among other examples.

As shown in FIG. 3, the device region 305 further includes the capacitor structure 210, where the capacitor structure 210 electrically couples with the transistor structure 205. The capacitor structure 210 may be in one or more metallization layers 340 (e.g., the metallization layers 340-1 through 340-m) of the device region 305.

The metallization layers 340 may be an electrical conductor and may comprise, consist of, or consist essentially of conductive material. The conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide), among other examples. Further, the metallization layers 340 may be separated by respective dielectric layers (excluded from FIG. 3 for clarity).

As further shown in the detailed view of FIG. 3, the capacitor structure 210 may include sets of conductive structures 345 (e.g., the sets of conductive structures 345-1 through 345-m) that are horizontally formed in the metallization layers 340. The sets of conductive structures 345 may be electrically coupled using sets of interconnect structures 350 (e.g., the sets of interconnect structures 350-1 through 350-m) that are vertically formed and that penetrate through dielectric layers (e.g., omitted from FIG. 3 for clarity) between the metallization layers 340. The sets of conductive structures 345 or the sets of interconnect structures 350 are electrical conductors and may comprise, consist of, or consist essentially of conductive material. The conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide), among other examples.

As further shown in the detailed view of FIG. 3, a conformal dielectric layer 355 may be over surfaces of the sets of conductive structures 345 or the sets of interconnect structures 350. In other words, the conformal dielectric layer 355 may be along external contours of the sets of conductive structures 345 or the sets of interconnect structures 350. The conformal dielectric layer 355 (e.g., an insulative layer) may be a high-k dielectric material. The high-k dielectric material may comprise, consist of, or consist essentially of a dielectric material such as hafnium oxide, hafnium silicate, zirconium dioxide, aluminum oxide, or titanium dioxide, among other examples.

As further shown in the detailed view of FIG. 3, a conductive fill structure 360 surrounds the conformal dielectric layer 355. The conductive fill structure 360 (e.g., a conductive layer) is an electrical conductor and may comprise, consist of, or consist essentially of conductive material. The conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide), among other examples.

As part of the capacitor structure 210, the sets of conductive structures 345 (two dimensional electrode structures) and the sets of interconnect structures 350 may be of a first electrical polarity. Additionally, or alternatively and as part of the capacitor structure 210, the conductive fill structure 360 (a three dimensional electrode structure) may be an electrode of a second, opposite electrical polarity. Additionally, or alternatively, the conformal dielectric layer 355 (e.g., a dielectric between electrodes of opposite electrical polarities) may be part of the capacitor structure 210.

As indicated above, the conformal dielectric layer 355 may include a high-k dielectric material. Additionally, or alternatively, the conformal dielectric layer 355 may include a dielectric material with a dielectric constant (e.g., a k-value) that is greater than or equal to approximately 3.9. If the conformal dielectric layer 355 includes a dielectric material with a dielectric constant that is less than 3.9, the capacitor structure 210 may fail to satisfy a performance threshold related to a capacitance, a charge storage, and electric field, or an energy density, among other examples. However, other values or ranges for the dielectric constant of the conformal dielectric layer 355 are within the scope of the present application.

The capacitor structure 210 may include at least a portion of one or more contact structures 365. For example, and as further shown in the detailed view of FIG. 3, the capacitor structure includes a portion of the contact structure 365-1 that electrically couples to the conductive fill structure 360 and a portion of the contact structure 365-2 that electrically couples to the conductive structure 345-1. The contact structures 365-1 and 365-2 may each be electrical conductors and may comprise, consist of, or consist essentially of conductive material. The conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide), among other examples.

As indicated above, FIG. 3 is provided as an example. Other examples may differ from what is described with regard to FIG. 3. For example, and although FIG. 3 shows a quantity three sets of conductive structures 345 dispersed across three metallization layers 340, some implementations may include two sets of the conductive structures 345 dispersed across two metallization layers 340, four sets of the conductive structures 345 dispersed across four metallization layers 340, and so on.

As described in connection with FIG. 1 through FIG. 3, and in some implementations, an integrated assembly includes a layered structure (e.g., the metallization layers 340-1 through 340-m). The layered structure includes a first set of conductive structures (e.g., the set of conductive structures 345-1) that are horizontally formed in a first metallization layer (e.g., the metallization layer 240-1). The layered structure includes a second set of conductive structures (e.g., the set of conductive structures 345-2) that are horizontally formed in a second metallization layer (e.g., the metallization layer 340-2). The layered structure includes a set of interconnect structures (e.g., the set of interconnect structures 350-1) that is vertically formed and electrically couples the first set of conductive structures and the second set of conductive structures. The layered structure includes a conformal dielectric layer (e.g., the conformal dielectric layer 355) over surfaces of the first set of conductive structures, surfaces of the second set of conductive structures, and surfaces the set of interconnect structures. The layered structure includes a conductive fill structure (e.g., the conductive fill structure 360) that surrounds the conformal dielectric layer.

Additionally, or alternatively and in some implementations, an apparatus (e.g., the semiconductor device 300) includes an integrated circuit (e.g., the charge pump 200). The integrated circuit includes a capacitor structure (e.g., the capacitor structure 210). The capacitor structure includes a first set of two dimensional electrode structures (e.g., the set of conductive structures 345-1) of a first polarity and a second set of two dimensional electrode structures (e.g., the set of conductive structures 345-2) of the first polarity that is away from the first set of two dimensional electrode structures. The capacitor structure includes a set of interconnect structures (e.g., the interconnect structures 350-1) that electrically couple the first set of two dimensional electrode structures with the second set of two dimensional electrode structures. The capacitor structure includes a conformal insulative layer along external contours of the first set of two dimensional electrode structures, the second set of two dimensional electrode structures, and the set of interconnect structures. The capacitor structure 210 includes a three dimensional electrode structure (e.g., the conductive fill structure 360) of a second polarity that surrounds the conformal insulative layer.

In these ways, the implementations the technical challenge of increasing storage densities of a memory device (e.g., a NAND device) by using the available three dimensional surfaces of one or several interconnect structures, thus significantly increasing capacitance per area (footprint). The implementations are scalable by adding more metallization layers and utilize a dedicated dielectric to optimize MIM capacitor characteristics, thereby overcoming the limitations of standard MIM capacitor configurations and traditional photolithographic processes.

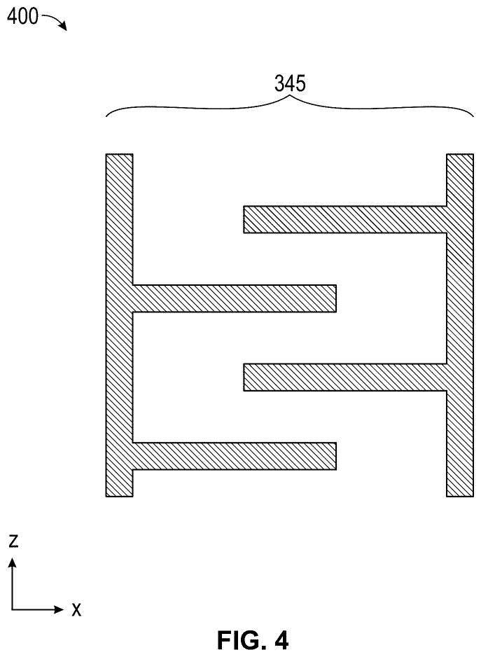

FIG. 4 is a diagrammatic view of an example implementation 400 of a set conductive structures (e.g., the set of conductive structures 345) described herein. The set of conductive structures 345 (e.g., electrodes) may be a set of two dimensional conductive structures that are horizontally formed in a metallization layer (e.g., of the metallization layers 340). In some implementations, multiples of the set of conductive structures 345 are formed across multiple metallization layers.

As shown in the top view of FIG. 4, the set of conductive structures 345 in implementation 400 may be interleaving pectinate (e.g., comb-like) conductive structures. However, other configurations, such as an array of linear conductive structures (e.g., beams), a honeycomb pattern of conductive structures, or a cross-hatched pattern of conductive structures, among other examples, are possible.

As indicated above, FIG. 4 is provided as an example. Other examples may differ from what is described with regard to FIG. 4.

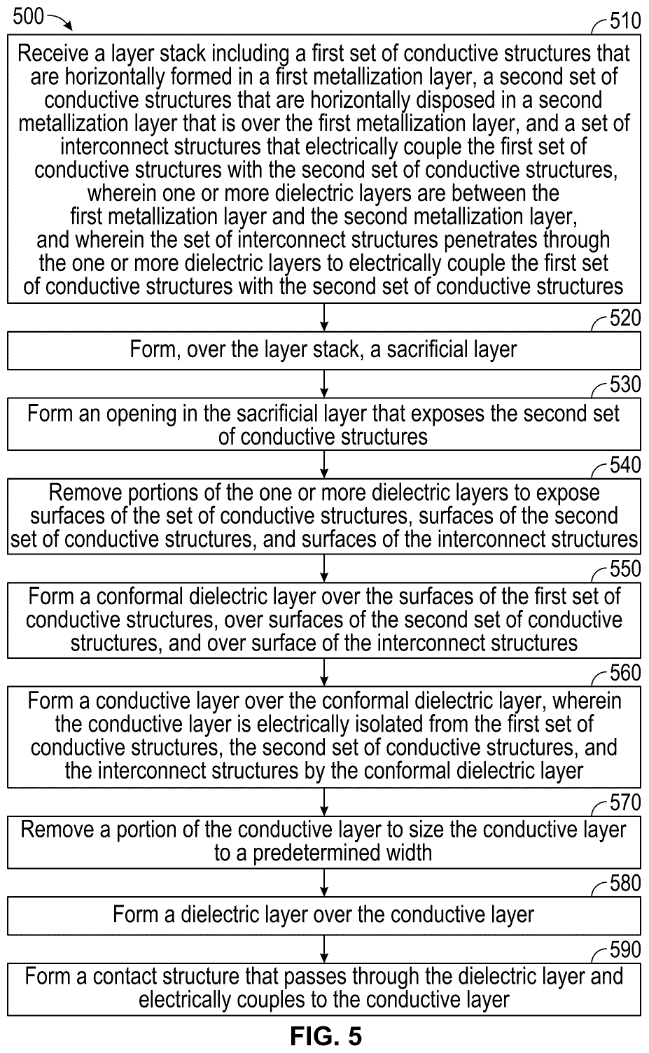

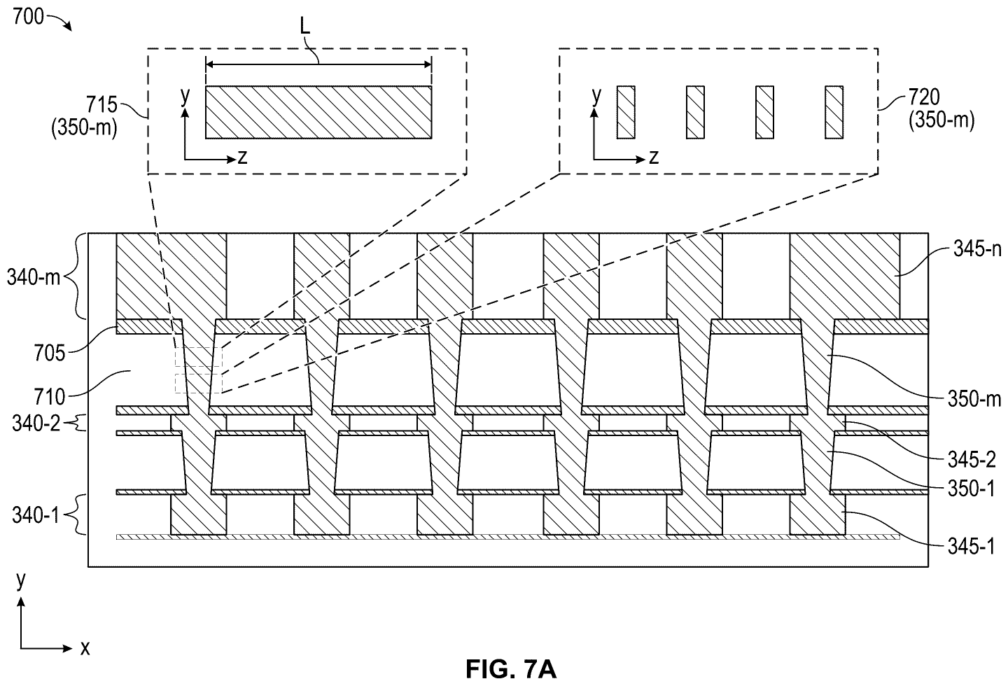

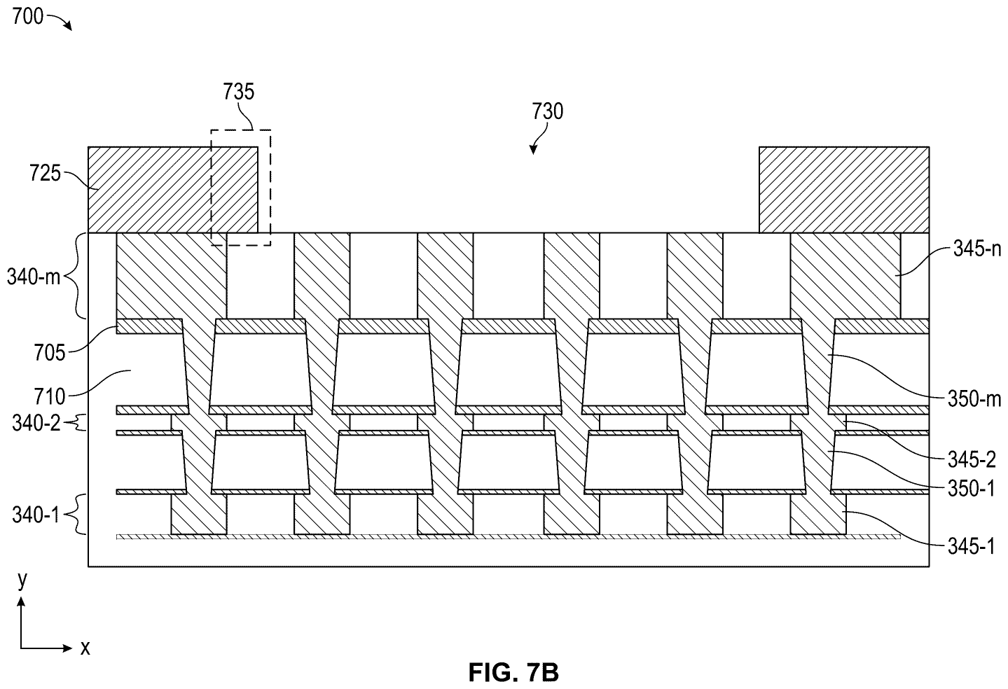

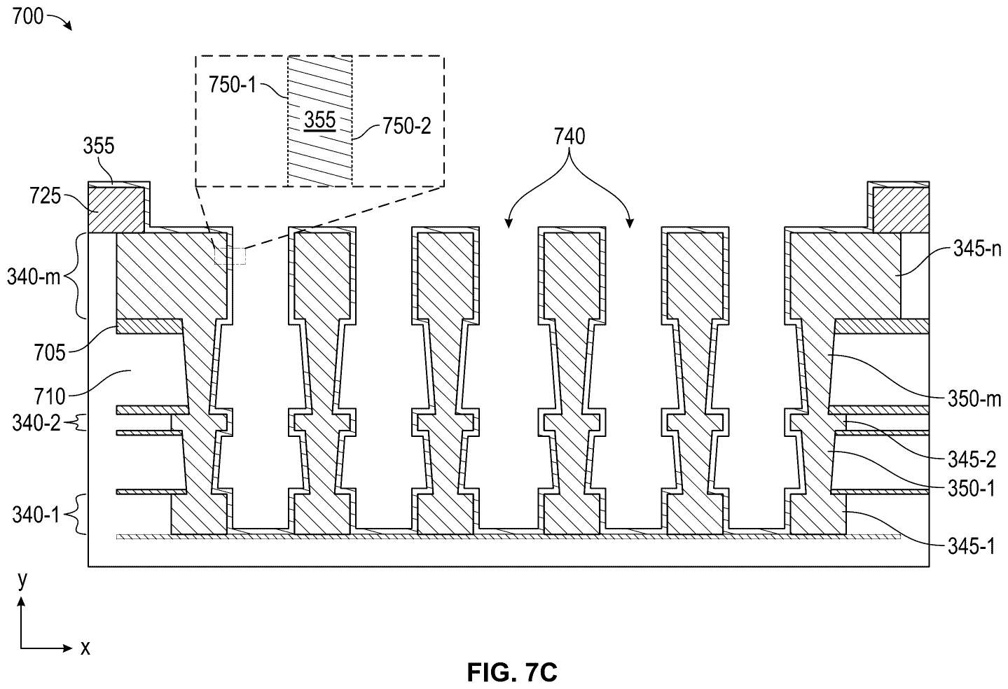

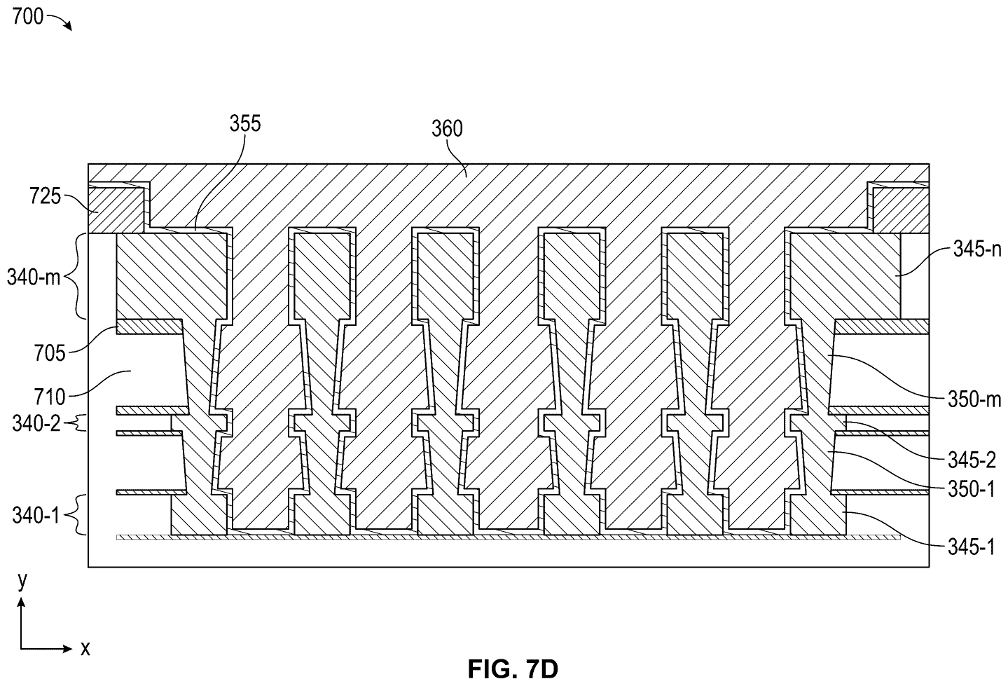

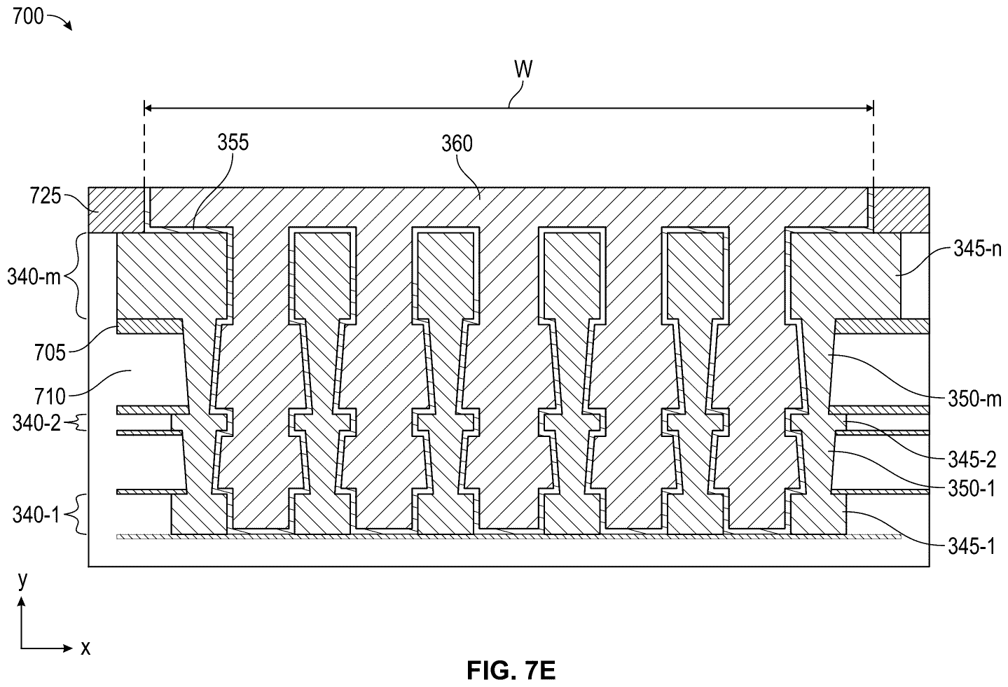

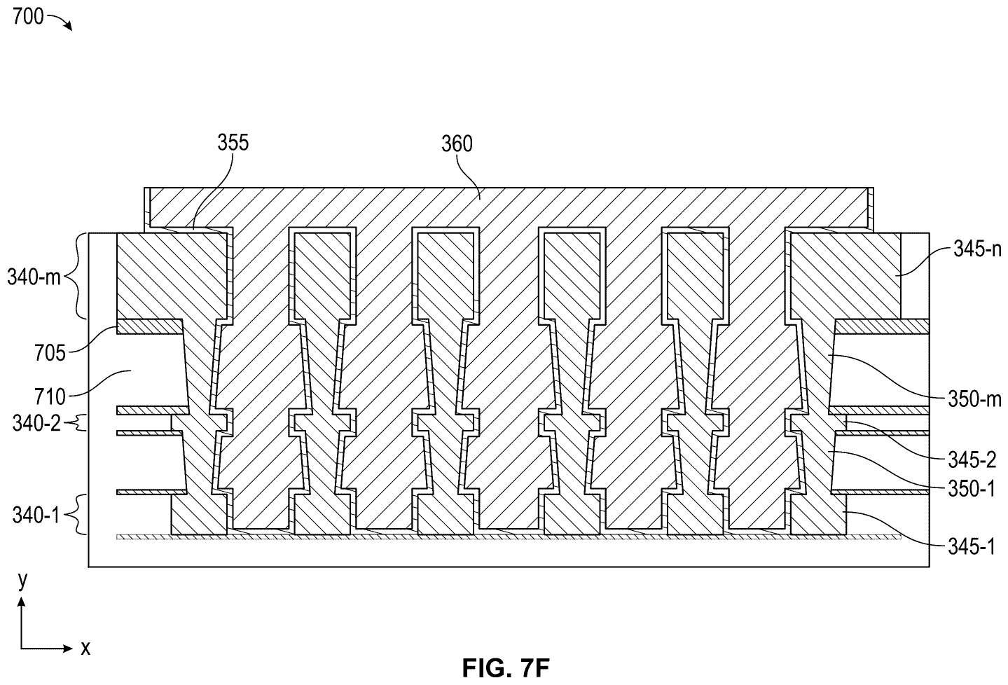

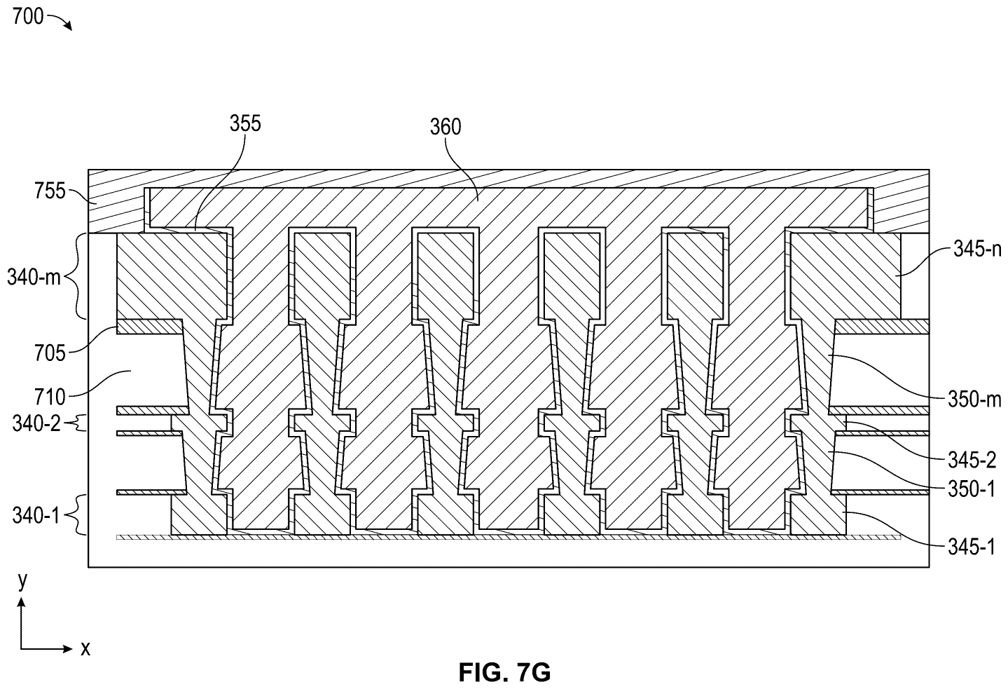

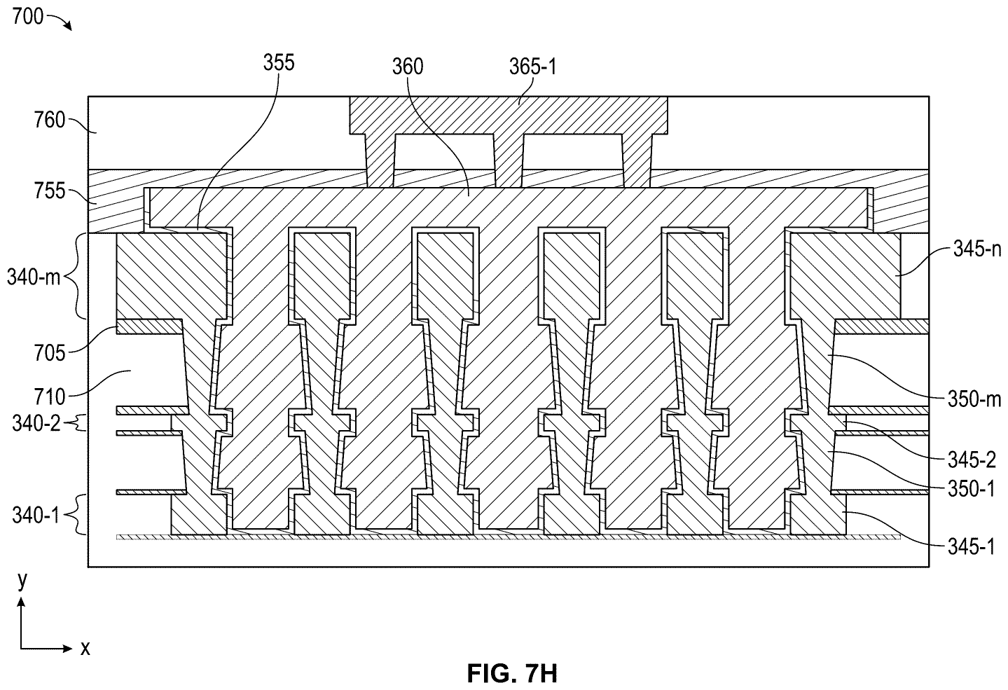

FIG. 5 is a flowchart of an example method 500 of forming an integrated assembly or memory device having a stack of metallization layers (e.g., the metallization layers 340) described herein. In some implementations, and as described in greater detail in connection with FIGS. 7A-7G, one or more process blocks of FIG. 5 may be performed by various semiconductor manufacturing equipment.

As shown in FIG. 5, the method 500 may include receiving a layer stack including a first set of conductive structures (e.g., the set of conductive structures 345-1) that are horizontally formed in a first metallization layer (e.g., the metallization layer 340-1), a second set of conductive structures (e.g., the set of conductive structures 345-2) that are horizontally formed in a second metallization layer (e.g., the metallization layer 340-2) that is over the first metallization layer, and a set of interconnect structures (e.g., the set of interconnect structures 350-1) that electrically couple the first set of conductive structures with the second set of conductive structures. In some implementations, one or more dielectric layers are between the first metallization layer and the second metallization layer. In some implementations, the set of interconnect structures penetrates through the one or more dielectric layers to electrically couple the first set of conductive structures with the second set of conductive structures (block 510). As further shown in FIG. 5, the method 500 may include forming, over the layer stack, a sacrificial layer (block 520). As further shown in FIG. 5, the method 500 may include forming an opening in the sacrificial layer that exposes the second set of conductive structures (block 530). As further shown in FIG. 5, the method 500 may include removing portions of the one or more dielectric layers to expose surfaces of the first set of conductive structures, surfaces of the second set of conductive structures, and surfaces of the interconnect structures (block 540). As further shown in FIG. 5, the method 500 may include forming a conformal dielectric layer (e.g., the conformal dielectric layer 355) over the surfaces of the first set of conductive structures, over surfaces of the second set of conductive structures, and over surfaces of the interconnect structures (block 550). As further shown in FIG. 5, the method 500 may include forming a conductive layer (e.g., the conductive fill structure 360) over the conformal dielectric layer. In some implementations, the conductive layer is electrically isolated from the first set of conductive structures, the second set of conductive structures, and the interconnect structures by the conformal dielectric layer (block 560). As further shown in FIG. 5, the method 500 may include removing a portion of the conductive layer to size the conductive layer to a predetermined width (block 570). As further shown in FIG. 5, the method 500 may include forming a dielectric layer over the conductive layer (block 580). As further shown in FIG. 5, the method 500 may include forming a contact structure (e.g., the contact structure 365-1) that passes through the dielectric layer and electrically couples to the conductive layer (block 590).

The method 500 may include additional aspects, such as any single aspect or any combination of aspects described below or in connection with one or more other methods described elsewhere herein.

In a first aspect, forming the sacrificial layer includes forming a carbon layer.

In a second aspect, alone or in combination with the first aspect, forming the opening in the sacrificial layer includes forming an opening in the carbon layer that leaves at least one portion of the carbon layer overhanging a portion of the second set of conductive structures.

In a third aspect, alone or in combination with one or more of the first and second aspects, removing portions of the one or more dielectric layers includes removing the portions using a wet etch operation, or removing the portions using a dry etch operation.

In a fourth aspect, alone or in combination with one or more of the first through third aspects, the set of interconnect structures includes at least one slab-like structure that extends substantially along a length of the first set of interconnect structures and a length of the second set of interconnect structures. In some implementations, at least one slab-like structure performs as a barrier to increase a uniformity of the wet etch operation or the dry etch operation.

In a fifth aspect, alone or in combination with one or more of the first through fourth aspects, forming the conformal dielectric layer includes forming the conformal dielectric layer using an atomic layer deposition operation.

In a sixth aspect, alone or in combination with one or more of the first through fifth aspects, the method 500 includes forming a barrier layer over the surfaces of the first set of conductive structures, over the surfaces of the second set of conductive structures, and over the surfaces of the interconnect structures prior to forming the conformal dielectric layer.

In a seventh aspect, alone or in combination with one or more of the first through sixth aspects, the method 500 includes forming a barrier layer over the conformal dielectric layer prior to forming the conductive fill structure.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the stack of metallization layers (e.g., the metallization layers 340), an integrated assembly that includes the stack of metallization layers, any part described herein of stack of metallization layers or any part described herein of an integrated assembly that includes the stack of metallization layers. For example, the method 500 may include forming one or more of the charge pump 200, the capacitor structure 210, or the semiconductor device 300. Furthermore, one or more of the blocks of the method 500 may be repeated or altered to form a third set of conductive structures in a third metallization layer, a fourth set of conductive structures in a fourth metallization layer, and so on.

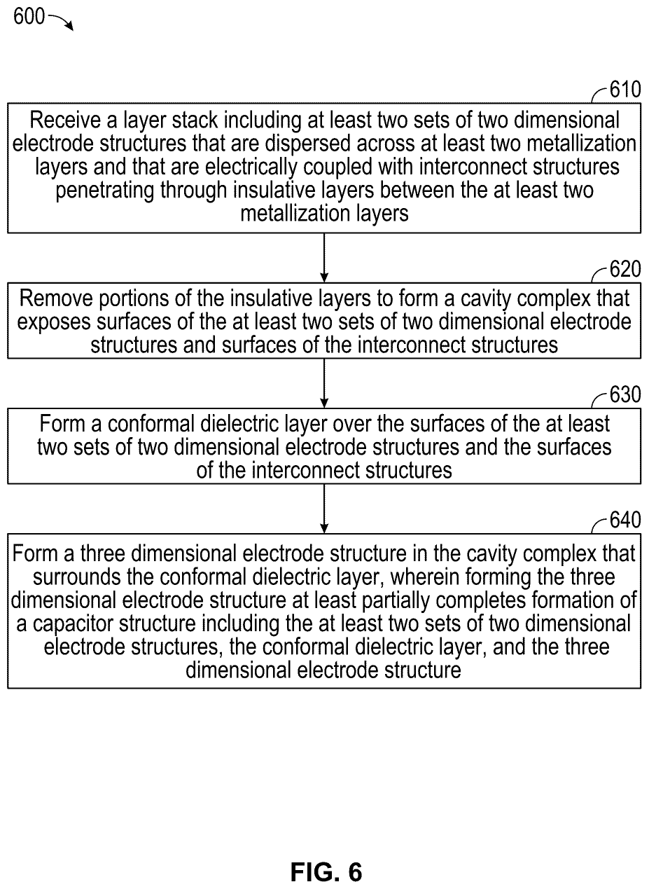

FIG. 6 is a flowchart of an example method 600 of forming an integrated assembly or memory device (e.g., the semiconductor device 300) having a capacitor structure (e.g., the capacitor structure 210) described herein. In some implementations, and as described in greater detail in connection with FIGS. 7A-7G, one or more process blocks of FIG. 6 may be performed by various semiconductor manufacturing equipment.

As shown in FIG. 6, the method 600 may include receiving a layer stack including at least two sets of two dimensional electrode structures (e.g., the set of conductive structures 345-1 and the set of conductive structures 345-2) that are dispersed across at least two metallization layers (e.g., the metallization layer 340-1 and the metallization layer 340-2) and that are electrically coupled with interconnect structures (e.g., the set of interconnect structures 350-1) penetrating through insulative layers between the at least two metallization layers (block 610). As further shown in FIG. 6, the method 600 may include removing portions of the insulative layers to form a cavity complex that exposes surfaces of the at least two sets of two dimensional electrode structures and surfaces of the interconnect structures (block 620). As further shown in FIG. 6, the method 600 may include forming a conformal insulative layer (e.g., the conformal dielectric layer 355) over the surfaces of the at least two sets of two dimensional electrode structures and the surfaces of the interconnect structures (block 630). As further shown in FIG. 6, the method 600 may include forming a three dimensional electrode structure (e.g., the conductive fill structure 360) in the cavity complex that surrounds the conformal insulative layer. In some implementations, forming the three dimensional electrode structure at least partially completes formation of a capacitor structure (e.g., the capacitor structure 210) including the at least two sets of two dimensional electrode structures, the conformal insulative layer, and the three dimensional electrode structure (block 640).

The method 600 may include additional aspects, such as any single aspect or any combination of aspects described below or in connection with one or more other methods described elsewhere herein.

In a first aspect, removing the portions of the insulative layers includes exposing a surface an approximately planar surface of a slab-like structure that corresponds to at least one of the interconnect structures.

In a second aspect, alone or in combination with the first aspect, removing the portions of the insulative layers includes forming a mask structure over the layer stack, and exhuming the portions through an opening in the mask structure.

In a third aspect, alone or in combination with one or more of the first and second aspects, forming the three dimensional electrode structure includes depositing a conductive material in the cavity complex over the conformal insulative layer, and planarizing the conductive material.

In a fourth aspect, alone or in combination with one or more of the first through third aspects, planarizing the conductive material includes using a chemical mechanical planarization operation, wherein the chemical mechanical planarization operation uses the mask structure as a hard stop and sizes the conductive material to a desired width.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the capacitor structure 210 and integrated assembly that includes the capacitor structure 210, any part described herein of the capacitor structure 210, or any part described herein of an integrated assembly that includes the capacitor structure 210. For example, the method 600 may include forming the memory cell 100 or the charge pump 200, among other examples.

FIG. 7A through FIG. 7H are diagrammatic views showing formation of a capacitor structure (e.g., the capacitor structure 210) at example process stages of an example process 700 of forming the capacitor structure. In some implementations, the example process described below in connection with FIG. 7A through FIG. 7H may correspond to the method 500, one or more blocks of the method 500, the method 600, or one or more blocks of the method 600. However, the process described below is an example, and other example processes may be used to form the capacitor structure, integrated assembly that includes the capacitor structure, or one or more parts of the capacitor structure or a semiconductor device (e.g., the semiconductor device 300).

As shown in FIG. 7A, the process 700 may include receiving a layer stack including the metallization layers 340 (e.g., the metallization layers 340-1 through 340-m), where the sets of conductive structures 345 (e.g., two dimensional electrode structures corresponding to the sets of conductive structures 345-1 through 345-n) are included in the metallization layers 340. As further shown in FIG. 7A, the sets of interconnect structures 350 (e.g., the sets of interconnect structures 350-1 through 350-m) may be included in the layer stack and electrically couple the sets of conductive structures 345.

In some implementations, one or more dielectric layers (e.g., the dielectric layers 705 and 710) may be interspersed with or be between the metallization layers 340. The dielectric layers 705 and 710 may include insulative materials. The insulative materials may comprise, consist of, or consist essentially of silicon dioxide or silicon nitride, among other examples. In some implementations, an insulative material of the dielectric layer 705 may be a same insulative material as or a different insulative material than an insulative material of the dielectric layer 710.

In some implementations, and as shown in the side detail view 715, one or more of the sets of interconnect structures 350 (e.g., the set of interconnect structures 350-m) may include a slab-like structure. The slab-like structure may extend substantially along a length L of the sets of conductive structures 345. As described in greater detail in connection with FIG. 7C, the slab-like structure may divert or inhibit a flow of an etchant to improve a uniformity of an etch operation that removes portions of the dielectric layers 705 and 710 to expose surfaces of the sets of conductive structures 345 and the sets of interconnect structures 350.

Additionally, or alternatively and as shown in the side detail view 720, one or more of the sets of interconnect structures 350 (e.g., the set of interconnect structures 350-m) may include at least two column-like structures. As described in greater detail in connection with FIG. 7C, the at least two column-like structures may promote a flow of an etchant to improve uniformity of an etch operation that removes portions of the dielectric layers 705 and 710 to expose surfaces of the sets of conductive structures 345 and the sets of interconnect structures 350.

In some implementations, the sets of interconnect structures 350 may include combinations of slab-like structures or column-like structures. A particular combination of slab-like structures or column-like structures may be selected based on factors including a number of metallization layers, a desired etch profile, or an etch recipe (e.g., an etchant or etch duration) used to remove portions of the dielectric layers 705 and 710, among other examples.

As shown in FIG. 7B, the process 700 may include forming a sacrificial layer 725 over the layer stack and forming an opening 730 in the sacrificial layer to expose at least a portion of an upper-most set of conductive structures (e.g., the set of conductive structures 345-n). In other words, the process 700 may include forming a hard mask structure over the layer stack.

In some implementations, forming the sacrificial layer 725 includes include forming (e.g., depositing or growing) a sacrificial material on the layer stack. The sacrificial material may include carbon, among other examples.

In some implementations, forming the opening 730 may include removing (e.g., etching) a portion of the sacrificial layer 725 to form the opening 730. The removal may remove all material in the sacrificial layer 725 down to top-most set of conductive structures. In some implementations, one or more photoresist masks may be used to form the opening 730. For example, one or more photoresist masks may be deposited or patterned on the sacrificial layer 725 prior to removing material to form the opening 730.

In some implementations, forming the opening 730 includes forming one or more overhang portions 735 that extend inwards from outermost conductive structures of the sets of conductive structures 345. As described in greater detail in connection FIG. 7C, the one or more overhang portions 735 may account for pullback of the sacrificial layer 725 during the etch operation that removes portions of the dielectric layers 705 and 710 to expose surfaces of the sets of conductive structures 345 and the sets of interconnect structures 350.

As shown in FIG. 7C, the process 700 may include removing the portions of the dielectric layers 705 and 710 and portions of the sacrificial layer 725 to form a cavity complex 740. Removing the portions of the dielectric layers 705 and 710 may include using an etch operation (e.g., a wet etch operation or a dry etch operation) that exhumes the portions of the dielectric layers 705 and 710 through the opening 730. As described in connection with FIG. 7A, slab-like or column-like structures (e.g., included in the sets of interconnect structures 350-1 through 350-m) may alter a flow of an etchant to improve a uniformity of the etch operation or change an etch profile associated with forming the cavity complex 740. Furthermore, and as described in connection with FIG. 7B, the etch operation may pull back (e.g., laterally etch) portions of the sacrificial layer 725 (e.g., the overhang portions 735) to expose top surfaces of the upper-most set of conductive structures (e.g., the set of conductive structures 345-n).

As further shown in FIG. 7C, the process 700 may include forming the conformal dielectric layer 355 (e.g., a conformal insulative layer) over or on exposed surfaces of the sets of conductive structures 345 or the sets of interconnect structures 350. Forming the conformal dielectric layer 355 may include using an atomic layer deposition operation, among other examples.

As further shown in detail view 745 of FIG. 7C, the process 700 may include forming one or more barrier layers 750 (e.g., the barrier layer 750-1 or the barrier layer 750-2). The one or more barrier layers 750 may comprise, consist of, or consist essentially of conductive material. For example, the conductive material may comprise, consist of, or consist essentially of titanium nitride. Alternatively, the conductive material may comprise, consist of, or consist essentially a metal (e.g., titanium, tungsten, cobalt, nickel, platinum, or ruthenium) or a metal composition (e.g., a metal silicide, a metal carbide, or a metal nitride, such as titanium silicon nitride), among other examples.

In some implementations, the process 700 includes forming the barrier layer 750-1 (e.g., depositing or growing) on exposed surfaces of the sets of conductive structures 345 and the sets of interconnect structures 350 prior to forming the conformal dielectric layer 355 (e.g., the barrier layer 750-1 is between the conformal dielectric layer 355 and surfaces of sets of conductive structures 345 and the sets of interconnect structures 350). Additionally, or alternatively and in some implementations, the process 700 includes forming the barrier layer 750-2 (e.g., depositing or growing) on the conformal dielectric layer 355 after formation of the conformal dielectric layer 355. The barrier layer 750-1 or the barrier layer 750-2 may enhance a performance of a capacitor structure (e.g., the capacitor structure 210) including the conformal dielectric layer 355 by preventing interdiffusion characteristics, reducing leakage, providing thermal stability, or enhancing interlayer adhesion, among other examples.

As shown in FIG. 7D, the process 700 may include forming the conductive fill structure 360 over or on the conformal dielectric layer 355. In some implementations, forming the conductive fill structure 360 (e.g., a conductive layer or a three dimensional electrode structure) includes forming (e.g., depositing or growing) the conductive fill structure 360 on the conformal dielectric layer 355. In some implementations, forming the conductive fill structure 360 includes forming (e.g., depositing or growing) the conductive fill structure 360 on a barrier layer (e.g., the barrier layer 750-2 of FIG. 7C).

As shown in FIG. 7E, the process 700 may include removing a portion of the conductive fill structure 360. Removing the portion of the conductive fill structure 360 may include planarizing a top surface of the conductive fill structure 360 using chemical-mechanical polishing or another suitable planarization operation. Removing the portion of the conductive fill structure 360 may further include removing a portion of the sacrificial layer 725 using chemical-mechanical polishing or another suitable planarization operation (e.g., the sacrificial layer 725 may perform as a hard stop). In some implementations, removing the portion of the conductive fill structure 360 sizes the conductive fill structure 360 to a width W that controls a capacitance of a capacitor (e.g., the capacitor structure 210) including the conductive fill structure 360.

As shown in FIG. 7F, the process 700 may include removing remaining portions of the sacrificial layer 725. Removing the remaining portions of the sacrificial layer 725 may include stripping the remaining portions of the sacrificial layer 725 using a cleaning operation (e.g., a wet chemical cleaning or plasma cleaning operation), among other examples.

As shown in FIG. 7G, the process 700 may include forming a dielectric layer 755 over or on the conductive fill structure 360. Forming the dielectric layer 755 over or on the conductive fill structure 360 may include forming (e.g., depositing or growing) an insulative material over or on the conductive fill structure 360. The insulative material may comprise, consist of, or consist essentially silicon dioxide or silicon nitride, among other examples.

As shown in FIG. 7H, the process 700 may include forming a dielectric layer over or on the dielectric layer 755. Forming the dielectric layer 760 over or on the dielectric layer 755 may include forming (e.g., depositing or growing) an insulative material over or on the conductive fill dielectric layer 755. The insulative material may comprise, consist of, or consist essentially silicon dioxide or silicon nitride, among other examples.

Furthermore, and as shown in FIG. 7H, the process 700 may include forming the conductive structure 365-1 through the dielectric layer 760 and the dielectric layer 755 to electrically couple with the conductive fill structure 360. In some implementations, forming the conductive structure 365-1 through the dielectric layer 760 and the dielectric layer 755 includes etching a cavity complex in the dielectric layer 760 and the dielectric layer 755, and subsequently forming (e.g., depositing or growing) a conductive material in the cavity complex. For example, the conductive material may comprise, consist of, or consist essentially of titanium nitride. Alternatively, the conductive material may comprise, consist of, or consist essentially a metal (e.g., titanium, tungsten, cobalt, nickel, platinum, or ruthenium) or a metal composition (e.g., a metal silicide, a metal carbide, or a metal nitride, such as titanium silicon nitride), among other examples.

As indicated above, the process steps described in connection with FIG. 7A through FIG. 7H are provided as examples. Other examples may differ from what is described with respect to FIG. 7A through FIG. 7H. The structure shown in FIG. 7H may be equivalent to the capacitor structure 210 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

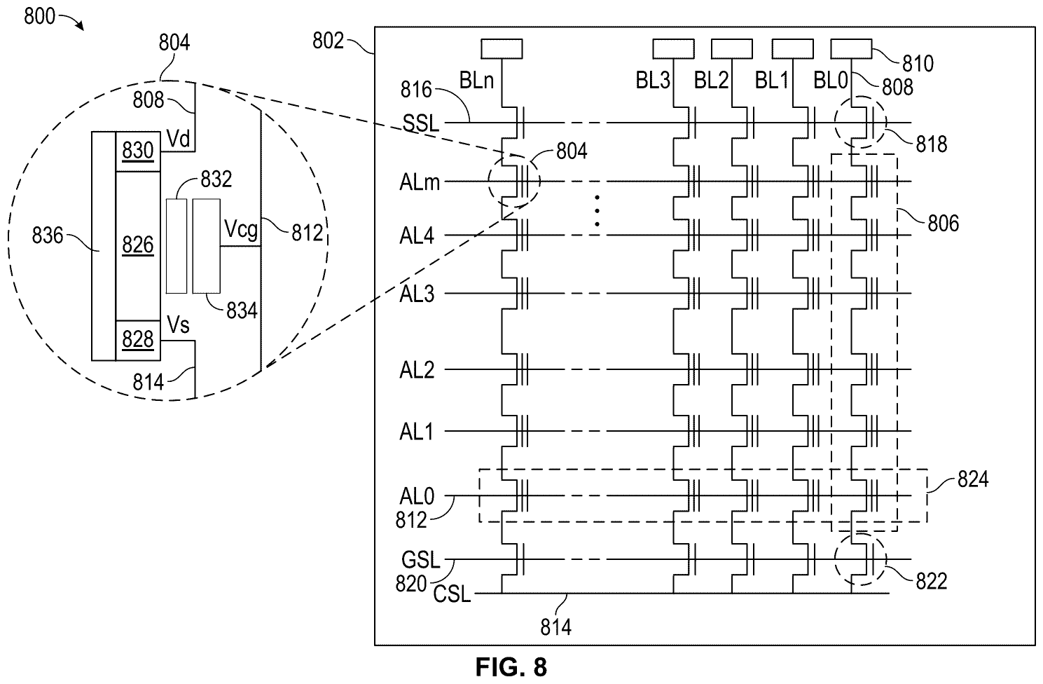

FIG. 8 is a diagram of an example implementation 800 of a memory array 802 described herein. In FIG. 8, the memory array 802 is a NAND memory array. However, in some implementations, the memory array 802 may be another type of memory array, such as a NOR memory array, a resistive RAM (RRAM) memory array, a magnetoresistive RAM (MRAM) memory array, a ferroelectric RAM (FRAM) memory array, a spin-transfer torque RAM (STT-RAM) memory array, or the like. In some implementations, the memory array 802 is part of a three-dimensional stack of memory arrays, such as 3D NAND flash memory, 3D NOR flash memory, or the like.

The memory array 802 includes multiple memory cells 804. A memory cell 804 may store an analog value, such as an electrical voltage or an electrical charge, that represents a data state (e.g., a digital value). The analog value and corresponding data state depend on a quantity of electrons trapped or present within a region of the memory cell 804 (e.g., in a charge trap, such as a floating gate), as described below.

In some implementations, one or more of the memory cells 804 may electrically couple with a charge pump (e.g., the charge pump 200 of FIG. 2). In some implementations, the charge pump includes a capacitor structure (e.g., the capacitor structure 210) using surfaces of three dimensional structures formed across multiple metallization layers (e.g., the metallization layers 340) of a device region (e.g., the device region 305).

A NAND string 806 (sometimes called a string) may include multiple memory cells 804 connected in series. A NAND string 806 is coupled to a bit line 808 (sometimes called a digit line or a column line, and shown as BLO-BLn). Data can be read from or written to the memory cells 804 of a NAND string 806 via a corresponding bit line 808 using one or more input/output (I/O) components 810 (e.g., an I/O circuit, an I/O bus, a page buffer, or a sensing component, such as a sense amplifier). Memory cells 804 of different NAND strings 806 (e.g., one memory cell 804 per NAND string 806) may be coupled with one another via access lines 812 (sometimes called word lines or row lines, and shown as AL0-ALm) that select which row (or rows) of memory cells 804 is affected by a memory operation (e.g., a read operation or a write operation).

A NAND string 806 may be connected to a bit line 808 at one end and a common source line (CSL) 814 at the other end. A string select line (SSL) 816 may be used to control respective string select transistors 818. A string select transistor 818 selectively couples a NAND string 806 to a corresponding bit line 808. A ground select line (GSL) 820 may be used to control respective ground select transistors 822. A ground select transistor 822 selectively couples a NAND string 806 to the common source line 814.

A “page” of memory (or “a memory page”) may refer to a group of memory cells 804 connected to the same access line 812, as shown by reference number 824. In some implementations (e.g., for single-level cells), the memory cells 804 connected to an access line 812 may be associated with a single page of memory. In some implementations (e.g., for multi-level cells), the memory cells 804 connected to an access line 812 may be associated with multiple pages of memory, where each page represents one bit stored in each of the memory cells 804 (e.g., a lower page that represents a first bit stored in each memory cell 804 and an upper page that represents a second bit stored in each memory cell 804). In NAND memory, a page is the smallest physically addressable data unit for a write operation (sometimes called a program operation).

In some implementations, a memory cell 804 is a floating-gate transistor memory cell. In this case, the memory cell 804 may include a channel 826, a source region 828, a drain region 830, a floating gate 832, and a control gate 834. The source region 828, the drain region 830, and the channel 826 may be on a substrate 836 (e.g., a semiconductor substrate). A memory device may store a data state in the memory cell 804 by charging the floating gate 832 to a particular voltage associated with the data state or to a voltage that is within a range of voltages associated with the data state. This results in a predefined amount of current flowing through the channel 826 (e.g., from the source region 828 to the drain region 830) when a specified read voltage is applied to the control gate 834 (e.g., by a corresponding access line 812 connected to the control gate 834). Although not shown, a tunnel oxide layer (or tunnel dielectric layer) may be interposed between the floating gate 832 and the channel 826, and a gate oxide layer (e.g., a gate dielectric layer) may be interposed between the floating gate 832 and the control gate 834. As shown, a drain voltage Vd may be supplied from a bit line 808, a control gate voltage Veg may be supplied from an access line 812, and a source voltage Vs may be supplied via the common source line 814 (which, in some implementations, is a ground voltage).

To write or program the memory cell 804, Fowler-Nordheim tunneling may be used. For example, a strong positive voltage potential may be created between the control gate 834 and the channel 826 (e.g., by applying a large positive voltage to the control gate 834 via a corresponding access line 812) while current is flowing through the channel 826 (e.g., from the common source line 814 to the bit line 808, or vice versa). The strong positive voltage at the control gate 834 causes electrons within the channel 826 to tunnel through the tunnel oxide layer and be trapped in the floating gate 832. These negatively charged electrons then act as an electron barrier between the control gate 834 and the channel 826 that increases the threshold voltage of the memory cell 804. The threshold voltage is a voltage required at the control gate 834 to cause current (e.g., a threshold amount of current) to flow through the channel 826. Fowler-Nordheim tunneling is an example technique for storing a charge in the floating gate, and other techniques, such as channel hot electron injection, may be used.

To read the memory cell 804, a read voltage may be applied to the control gate 834 (e.g., via a corresponding access line 812), and an I/O component 810 (e.g., a sense amplifier) may determine the data state of the memory cell 804 based on whether current passes through the memory cell 804 (e.g., the channel 826) due to the applied voltage. A pass voltage may be applied to all memory cells 804 (other than the memory cell 804 being read) in the same NAND string 806 as the memory cell 804 being read. For example, the pass voltage may be applied on each access line 812 other than the access line 812 of the memory cell 804 being read (e.g., where the read voltage is applied). The pass voltage is higher than the highest read voltage associated with any memory cell data states so that all of the other memory cells 804 in the NAND string 806 conduct, and the I/O component 810 can detect a data state of the memory cell 804 being read by sensing current (or lack thereof) on a corresponding bit line 808. For example, in a single-level memory cell that stores one of two data states, the data state is a “1” if current is detected, and the data state is a “0” if current is not detected. In a multi-level memory cell that stores one of three or more data states, multiple read voltages are applied, over time, to the control gate 834 to distinguish between the three or more data states and determine a data state of the memory cell 804.

To erase the memory cell 804, a strong negative voltage potential may be created between the control gate 834 and the channel 826 (e.g., by applying a large negative voltage to the control gate 834 via a corresponding access line 812). The strong negative voltage at the control gate 834 causes trapped electrons in the floating gate 832 to tunnel back across the oxide layer from the floating gate 832 to the channel 826 and to flow between the common source line 814 and the bit line 808. This removes the electron barrier between the control gate 834 and the channel 826 and decreases the threshold voltage of the memory cell 804 (e.g., to an empty or erased state, which may represent a “1”). In NAND memory, a block is the smallest unit of memory that can be erased. A block of NAND memory includes multiple pages. Thus, an individual page of a block cannot be erased without erasing every other page of the block. In some implementations, a block may be divided into multiple sub-blocks. A sub-block is a portion of a block and may include a subset of pages of the block or a subset of memory cells of the block.

As indicated above, FIG. 8 is provided as an example. Other examples may differ from what is described with regard to FIG. 8.

Although the capacitor structure 210 of FIG. 2 through FIG. 8 is described in implementations related to a NAND memory device, the implementations are by way of example only. The capacitor structure 210 may implemented with other types of integrated circuit devices, including other memory devices (e.g., DRAM memory devices), logic devices, radio frequency (RF) communication devices, application-specific integrated circuit (ASIC) devices, power management integrated circuit devices, or sensor integrated circuit devices, among other examples.

In some implementations, an integrated assembly includes a layered structure, comprising: a first set of conductive structures that are horizontally formed in a first metallization layer; a second set of conductive structures that are horizontally formed in a second metallization layer; a set of interconnect structures that is vertically formed and electrically couples the first set of conductive structures and the second set of conductive structures; a conformal dielectric layer over surfaces of the first set of conductive structures, surfaces of the second set of conductive structures, and surfaces the set of interconnect structures; and a conductive fill structure that surrounds the conformal dielectric layer.

In some implementations, an apparatus includes an integrated circuit, comprising: a capacitor structure, comprising: a first set of two dimensional electrode structures of a first polarity; a second set of two dimensional electrode structures of the first polarity that is away from the first set of two dimensional electrode structures; a set of interconnect structures that electrically couple the first set of two dimensional electrode structures with the second set of two dimensional electrode structures; a conformal insulative layer along external contours of the first set of two dimensional electrode structures, the second set of two dimensional electrode structures, and the set of interconnect structures; and a three dimensional electrode structure of a second polarity that surrounds the conformal insulative layer.

In some implementations, a method includes receiving a layer stack including a first set of conductive structures that are horizontally formed in a first metallization layer, a second set of conductive structures that are horizontally formed in a second metallization layer that is over the first metallization layer, and a set of interconnect structures that electrically couple the first set of conductive structures with the second set of conductive structures; wherein one or more dielectric layers are between the first metallization layer and the second metallization layer, and wherein the set of interconnect structures penetrates through the one or more dielectric layers to electrically couple the first set of conductive structures with the second set of conductive structures; forming, over the layer stack, a sacrificial layer; forming an opening in the sacrificial layer that exposes the second set of conductive structures; removing portions of the one or more dielectric layers to expose surfaces of the first set of conductive structures, surfaces of the second set of conductive structures, and surfaces of the interconnect structures; forming a conformal dielectric layer over the surfaces of the first set of conductive structures, over surfaces of the second set of conductive structures, and over surfaces of the interconnect structures; forming a conductive layer over the conformal dielectric layer, wherein the conductive layer is electrically isolated from the first set of conductive structures, the second set of conductive structures, and the interconnect structures by the conformal dielectric layer; removing a portion of the conductive layer to size the conductive layer to a predetermined width; and forming a dielectric layer over the conductive layer; and forming a contact structure that passes through the dielectric layer and electrically couples to the conductive layer.

In some implementations, a method includes receiving a layer stack including at least two sets of two dimensional electrode structures that are dispersed across at least two metallization layers and that are electrically coupled with interconnect structures penetrating through insulative layers between the at least two metallization layers; removing portions of the insulative layers to form a cavity complex that exposes surfaces of the at least two sets of two dimensional electrode structures and surfaces of the interconnect structures; forming a conformal insulative layer over the surfaces of the at least two sets of two dimensional electrode structures and the surfaces of the interconnect structures; and forming a three dimensional electrode structure in the cavity complex that surrounds the conformal insulative layer, wherein forming the three dimensional electrode structure at least partially completes formation of a capacitor structure including the at least two sets of two dimensional electrode structures, the conformal insulative layer, and the three dimensional electrode structure.

The foregoing disclosure provides illustration and description but is not intended to be exhaustive or to limit the implementations to the precise forms disclosed. Modifications and variations may be made in light of the above disclosure or may be acquired from practice of the implementations described herein.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, or assembly in use or operation in addition to the orientations depicted in the figures. A structure or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. As used herein, the term “formed” may, depending on the context, refer to an established state or a position of a first feature relative to a second feature, and not imply any specific method or sequence of formation.

Even though particular combinations of features are recited in the claims or disclosed in the specification, these combinations are not intended to limit the disclosure of implementations described herein. Many of these features may be combined in ways not specifically recited in the claims or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “or,” unless explicitly stated otherwise (e.g., if used in combination with “either” or “only one of”).

What is claimed is:

1. An integrated assembly, comprising:
a layered structure, comprising:
a first set of conductive structures that are horizontally formed in a first metallization layer;
a second set of conductive structures that are horizontally formed in a second metallization layer;
a set of interconnect structures that is vertically formed and electrically couples the first set of conductive structures and the second set of conductive structures;
a conformal dielectric layer over surfaces of the first set of conductive structures, surfaces of the second set of conductive structures, and surfaces the set of interconnect structures; and
a conductive fill structure that surrounds the conformal dielectric layer.

2. The integrated assembly of claim 1, wherein the set of interconnect structures comprises:
at least one slab-like structure extending substantially along a length of the first set of conductive structures and a length of the second set of conductive structures.

3. The integrated assembly of claim 1, where the set of interconnect structures comprises:
at least two column-like structures.

4. The integrated assembly of claim 1, wherein at least one of the first set of conductive structures or the second set of conductive comprises:
interleaving pectinate structures.

5. The integrated assembly of claim 1, wherein the conformal dielectric layer comprises:
a dielectric material having a dielectric constant that is greater than approximately 3.9.

6. The integrated assembly of claim 1, wherein the conformal dielectric layer comprises:
aluminum oxide.

7. The integrated assembly of claim 6, further comprising:
titanium nitride between the aluminum oxide and surfaces of the first set of conductive structures, surfaces of the second set of conductive structures, and the set of interconnect structures.

8. The integrated assembly of claim 6, further comprising:
titanium nitride between the aluminum oxide and the conductive fill structure.

9. The integrated assembly of claim 1, wherein the conductive fill structure comprises:
tungsten.

10. An apparatus, comprising:
an integrated circuit, comprising:
a capacitor structure, comprising:
a first set of two dimensional electrode structures of a first polarity;
a second set of two dimensional electrode structures of the first polarity that is away from the first set of two dimensional electrode structures;
a set of interconnect structures that electrically couple the first set of two dimensional electrode structures with the second set of two dimensional electrode structures;
a conformal insulative layer along external contours of the first set of two dimensional electrode structures, the second set of two dimensional electrode structures, and the set of interconnect structures; and
a three dimensional electrode structure of a second polarity that surrounds the conformal insulative layer.

11. The apparatus of claim 10, wherein capacitor structure is part of a charge pump.

12. The apparatus of claim 11, wherein the integrated circuit is a NAND memory circuit, and
wherein the charge pump is configured to generate a voltage that is greater than approximately 30 volts.

13. A method, comprising:
receiving a layer stack including a first set of conductive structures that are horizontally formed in a first metallization layer, a second set of conductive structures that are horizontally formed in a second metallization layer that is over the first metallization layer, and a set of interconnect structures that electrically couple the first set of conductive structures with the second set of conductive structures;
wherein one or more dielectric layers are between the first metallization layer and the second metallization layer, and
wherein the set of interconnect structures penetrates through the one or more dielectric layers to electrically couple the first set of conductive structures with the second set of conductive structures;
forming, over the layer stack, a sacrificial layer;
forming an opening in the sacrificial layer that exposes the second set of conductive structures;
removing portions of the one or more dielectric layers to expose surfaces of the first set of conductive structures, surfaces of the second set of conductive structures, and surfaces of the interconnect structures;
forming a conformal dielectric layer over the surfaces of the first set of conductive structures, over surfaces of the second set of conductive structures, and over surfaces of the interconnect structures;
forming a conductive layer over the conformal dielectric layer,
wherein the conductive layer is electrically isolated from the first set of conductive structures, the second set of conductive structures, and the interconnect structures by the conformal dielectric layer;
removing a portion of the conductive layer to size the conductive layer to a predetermined width;
forming a dielectric layer over the conductive layer; and
forming a contact structure that passes through the dielectric layer and electrically couples to the conductive layer.

14. The method of claim 13, wherein forming the sacrificial layer includes:
forming a carbon layer.

15. The method of claim 14, wherein forming the opening in the sacrificial layer includes:
forming an opening in the carbon layer that leaves at least one portion of the carbon layer overhanging a portion of the second set of conductive structures.

16. The method of claim 13, wherein removing portions of the one or more dielectric layers includes:
removing the portions using a wet etch operation, or
removing the portions using a dry etch operation.

17. The method of claim 16, wherein the set of interconnect structures includes at least one slab-like structure that extends substantially along a length of the first set of interconnect structures and a length of the second set of interconnect structures, and
wherein the at least one slab-like structure performs as a barrier to increase a uniformity of the wet etch operation or the dry etch operation.

18. The method of claim 13, wherein forming the conformal dielectric layer includes:
forming the conformal dielectric layer using an atomic layer deposition operation.

19. The method of claim 13, further including:
forming a barrier layer over the surfaces of the first set of conductive structures, over the surfaces of the second set of conductive structures, and over the surfaces of the interconnect structures prior to forming the conformal dielectric layer.

20. The method of claim 13, further including:
forming a barrier layer over the conformal dielectric layer prior to forming the conductive fill structure.

21. A method, comprising:
receiving a layer stack including at least two sets of two dimensional electrode structures that are dispersed across at least two metallization layers and that are electrically coupled with interconnect structures penetrating through insulative layers between the at least two metallization layers;
removing portions of the insulative layers to form a cavity complex that exposes surfaces of the at least two sets of two dimensional electrode structures and surfaces of the interconnect structures;
forming a conformal insulative layer over the surfaces of the at least two sets of two dimensional electrode structures and the surfaces of the interconnect structures; and
forming a three dimensional electrode structure in the cavity complex that surrounds the conformal insulative layer,
wherein forming the three dimensional electrode structure at least partially completes formation of a capacitor structure including the at least two sets of two dimensional electrode structures, the conformal insulative layer, and the three dimensional electrode structure.

22. The method of claim 21, wherein removing the portions of the insulative layers includes:
exposing a surface an approximately planar surface of a slab-like structure that corresponds to at least one of the interconnect structures.

23. The method of claim 21, wherein removing the portions of the insulative layers includes:
forming a mask structure over the layer stack, and
exhuming the portions through an opening in the mask structure.

24. The method of claim 23, wherein forming the three dimensional electrode structure includes:
depositing a conductive material in the cavity complex over the conformal insulative layer, and
planarizing the conductive material.

25. The method of claim 24, wherein planarizing the conductive material includes:
using a chemical mechanical planarization operation,
wherein the chemical mechanical planarization operation uses the mask structure as a hard stop and sizes the conductive material to a desired width.
